(19) United States
(12) Patent Application Publication
(10) Pub. No.: US 2026/0089446 A1
(43) Pub. Date: Mar. 26, 2026

(54) SEMICONDUCTOR STRUCTURE AND FABRICATION METHOD THEREOF

(71) Applicant: UNITED MICROELECTRONICS CORP., Hsin-Chu City (TW)

(72) Inventors: Chao-An Su, Kaohsiung City (TW); Weng-Yi Chen, Hsinchu County (TW); Chang-Sheng Hsu, Hsinchu City (TW); Shih-Wei Li, Taoyuan City (TW); Kuo-Hsuan Lo, Miaoli County (TW); Chia-Wen Wang, Hsinchu City (TW); Wen-Hao Cheng, Taoyuan City (TW)

(73) Assignee: UNITED MICROELECTRONICS CORP., Hsin-Chu City (TW)

(21) Appl. No.: 18/918,084

(22) Filed: Oct. 17, 2024

(30) Foreign Application Priority Data
Sep. 24, 2024 (TW) 113136107

(51) Int. Cl. H04R 19/00; B81B 3/00; B81C 1/00; H04R 7/04; H04R 7/18; H04R 19/02; H04R 31/00

(52) U.S. Cl. CPC H04R 19/005; B81B 3/0021; B81C 1/00158; H04R 7/04; H04R 7/18; H04R 19/02; H04R 31/003; B81B 2201/0257; B81B 2203/0127; B81B 2203/019; B81B 2203/0307; H04R 2201/003; H04R 2307/025

(57) ABSTRACT

A semiconductor structure includes a substrate having a cavity thereon; a membrane suspended above the cavity and anchored to the substrate, wherein the membrane comprises a central region, a peripheral suspension region, and a coil region between the central region and the peripheral suspension region; and a coil embedded in the coil region of the membrane, wherein the peripheral suspension region has a first concave portion and a first convex portion.

### BACKGROUND OF THE INVENTION

### 1. Field of the Invention

The present invention relates to the field of semiconductor technology, and in particular, to an improved semiconductor structure and a manufacturing method thereof.

### 2. Description of the Prior Art

Micro-Electro-Mechanical Systems (MEMS) integrate mechanical elements, sensors, and actuators onto a tiny chip through micro fabrication technology. A dynamic MEMS speaker applies the principle of traditional dynamic speakers to a miniaturized MEMS chip.

The working principle of a dynamic MEMS speaker is as follows: when an electric current passes through the coil on the diaphragm, it generates a magnetic field. This magnetic field interacts with the external magnetic field, producing an electromagnetic force that drives the diaphragm to vibrate and generate sound waves. Sound Pressure Level (SPL) is a physical quantity used to measure the loudness of sound. For speaker products, a higher SPL indicates a stronger sound output capability, which is a crucial factor in determining market acceptance. The diaphragm, as the direct medium for sound generation, plays a vital role in affecting the SPL. Its design significantly impacts the sound output performance.

### SUMMARY OF THE INVENTION

It is one object of the present invention to provide an improved semiconductor structure and a manufacturing method thereof to solve the deficiencies or shortcomings of the existing technology.

One aspect of the invention provides a semiconductor structure including a substrate having a cavity thereon; a membrane suspended above the cavity and anchored to the substrate, wherein the membrane comprises a central region, a peripheral suspension region, and a coil region between the central region and the peripheral suspension region; and a coil embedded in the coil region of the membrane, wherein the peripheral suspension region has a first concave portion and a first convex portion.

According to some embodiments, the membrane comprises a polymer film.

According to some embodiments, the polymer film comprises polyimide film or a polydimethylsiloxane film.

According to some embodiments, the membrane comprises a tensile dielectric film.

According to some embodiments, the tensile dielectric film comprises a silicon nitride film.

According to some embodiments, the first concave portion is contiguous with the first convex portion, and wherein an oblique sidewall is disposed between a bottom surface of the first concave portion and a top surface of the first convex portion.

According to some embodiments, a lower corner formed by an intersection of the oblique sidewall and the bottom surface of the first concave portion is an obtuse angle.

According to some embodiments, an upper corner formed by an intersection of the oblique sidewall and the top surface of the first convex portion is a rounded corner.

According to some embodiments, the first convex portion has a thickness X and the first concave portion has a thickness Y, wherein 0.2≤Y/X≤0.9.

According to some embodiments, the central region comprises a second concave portion.

Another aspect of the invention provides a method for forming a semiconductor structure. A substrate having a cavity thereon is provided. A membrane is formed on the substrate. The membrane is suspended above the cavity and anchored to the substrate. The membrane includes a central region, a peripheral suspension region, and a coil region between the central region and the peripheral suspension region. A coil is formed in the coil region of the membrane. The peripheral suspension region has a first concave portion and a first convex portion.

According to some embodiments, the membrane comprises a polymer film.

According to some embodiments, the polymer film comprises polyimide film or a polydimethylsiloxane film.

According to some embodiments, the membrane comprises a tensile dielectric film.

According to some embodiments, the tensile dielectric film comprises a silicon nitride film.

According to some embodiments, the first concave portion is contiguous with the first convex portion, and wherein an oblique sidewall is disposed between a bottom surface of the first concave portion and a top surface of the first convex portion.

According to some embodiments, a lower corner formed by an intersection of the oblique sidewall and the bottom surface of the first concave portion is an obtuse angle.

According to some embodiments, an upper corner formed by an intersection of the oblique sidewall and the top surface of the first convex portion is a rounded corner.

According to some embodiments, the first convex portion has a thickness X and the first concave portion has a thickness Y, wherein 0.2≤Y/X≤0.9.

According to some embodiments, the central region comprises a second concave portion.

One germane feature of this invention is to enhance the sound pressure level (SPL) of a MEMS speaker by introducing a concave-convex structure in the peripheral suspension area and/or central region of the diaphragm. This modification alters the resonant characteristics of the diaphragm.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view schematic diagram of a semiconductor structure according to an embodiment of the present invention.

FIG. 2 is a cross-sectional view taken along line I-I′ in FIG. 1.

FIG. 3 to FIG. 5 are schematic diagrams illustrating a method for forming the semiconductor structure according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

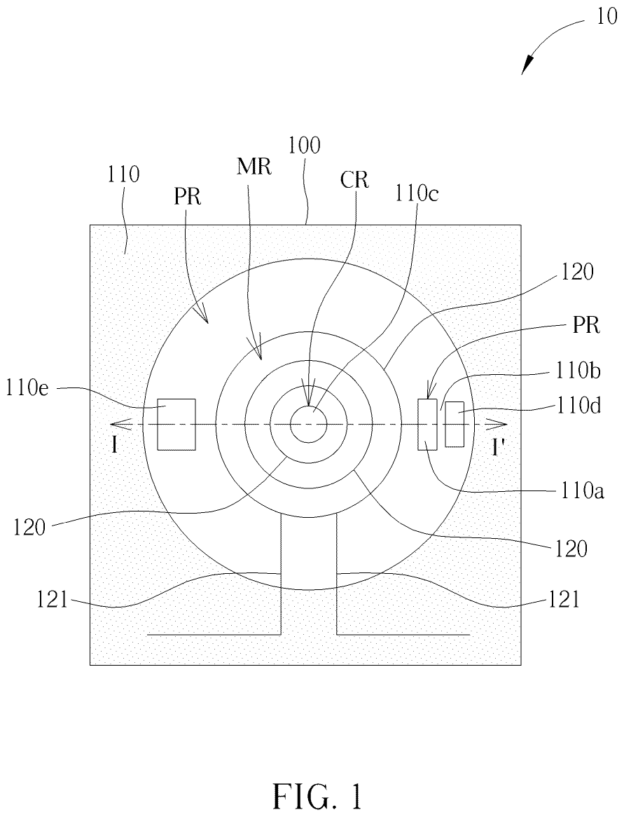

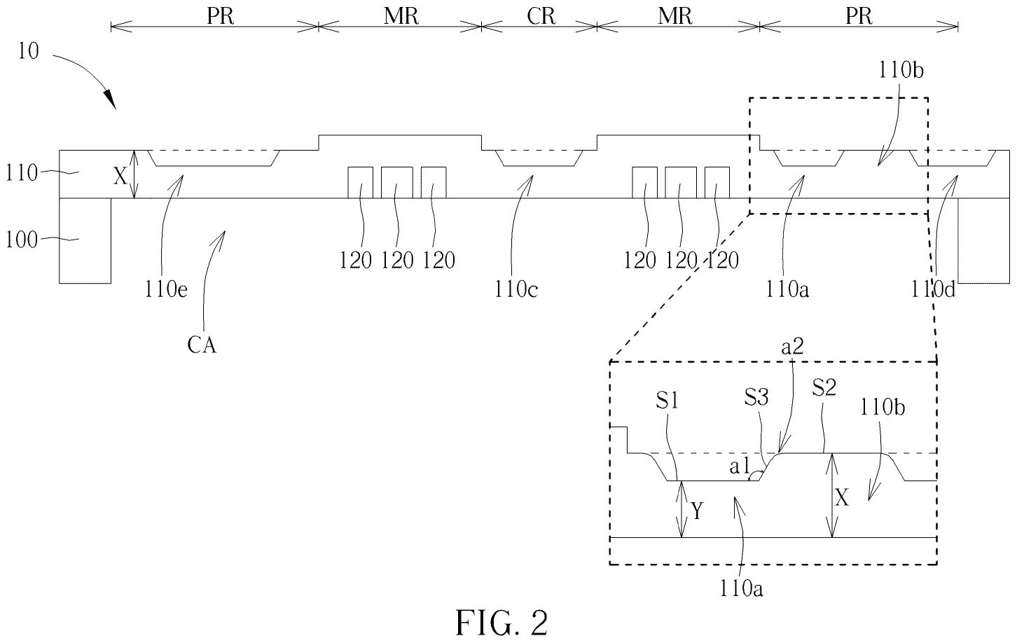

Referring to FIG. 1 and FIG. 2, FIG. 1 is a top view of a semiconductor structure 10 according to an embodiment of the present invention, and FIG. 2 is a cross-sectional view taken along line I-I′ in FIG. 1. The semiconductor structure 10 may be used as a component of a MEMS speaker. It will be appreciated by those skilled in the art that some details of the metal or dielectric layers in FIG. 2 are not shown.

As shown in FIG. 1 and FIG. 2, the semiconductor structure 10 includes a substrate 100 having a cavity CA therein. According to an embodiment of the present invention, for example, the substrate 100 may be a silicon substrate, but is not limited thereto. The semiconductor structure 10 further includes a diaphragm 110 suspended above the cavity CA, and the periphery of the diaphragm 110 is anchored to the upper surface of the substrate 100.

According to an embodiment of the present invention, the diaphragm 110 includes, for example, a polymer film. According to an embodiment of the present invention, the polymer film may include a polyimide (PI) film or a polydimethylsiloxane (PDMS) film. According to another embodiment of the present invention, the diaphragm 110 may include a tensile dielectric film. According to an embodiment of the present invention, the tensile dielectric film may include a silicon nitride film. According to an embodiment of the present invention, for example, the diaphragm 110 may be circular, and its diameter may be, for example, between 3-5 mm, but is not limited thereto.

According to an embodiment of the present invention, for example, the diaphragm 110 may include a central region CR, an annular, peripheral suspension region PR, and an annular coil region MR located between the central region CR and the peripheral suspension region PR.

According to an embodiment of the present invention, the semiconductor structure 10 further includes a coil pattern 120 embedded within the coil region MR of the diaphragm 110. According to an embodiment of the present invention, the diaphragm 110 may have a first concave portion 110a and a first convex portion 110b in the peripheral suspension region PR. According to an embodiment of the present invention, the coil pattern 120 may be connected to an external signal through a wire pattern 121. According to an embodiment of the present invention, the coil pattern 120 and the wire pattern 121 are made of, for example, aluminum or aluminum alloy, but are not limited thereto.

As shown in the partial enlarged view of FIG. 2, the first concave portion 110a is contiguous with the first convex portion 110b. An oblique sidewall S3 is provided between the bottom surface S1 of the first concave portion 110a and the top surface S2 of the first convex portion 110b. According to an embodiment of the present invention, for example, the bottom angle a1 formed by the intersection of the oblique sidewall S3 and the bottom surface S1 of the first concave portion 110a is an obtuse angle. According to an embodiment of the present invention, for example, the top angle a2 formed by the intersection of the oblique sidewall S3 and the top surface S2 of the first convex portion 110b is a rounded corner.

According to an embodiment of the present invention, the thickness of the first convex portion 110b is X (i.e., the original film thickness), and the thickness of the first concave portion 110a is Y, wherein 0.2≤Y/X≤0.9. According to an embodiment of the present invention, for example, X may be between 1-5 micrometers, preferably between 3-4 micrometers, but is not limited thereto.

It should be understood that the first concave portion 110a and the first convex portion 110b in the FIG. 1 may have various patterns, such as continuous or discontinuous annular, circular, or elliptical shapes. According to embodiments of the present invention, for example, the diaphragm 110 may further include a second concave portion 110c in the central region CR. For instance, the first concave portion 110a and the second concave portion 110c may have different patterns, shapes, or areas.

According to embodiments of the present invention, for example, the diaphragm 110 may further include a third concave portion 110d and a fourth concave portion 110e within the peripheral suspension region PR, and the first convex portion 110b may be located between the first concave portion 110a and the third concave portion 110d, and the fourth concave portion 110e may be located away from the first concave portion 110a and the third concave portion 110d. For example, the first concave portion 110a, the third concave portion 110d, and the fourth concave portion 110e within the peripheral suspension region PR may have mutually different patterns, shapes, or areas. According to embodiments of the present invention, the third concave portion 110d may overlap with the substrate 100, but is not limited thereto.

One germane feature of the present invention is that by providing a recessed and protruding structure feature in the peripheral suspension region PR and/or the central region CR of the diaphragm 110, the resonant characteristics of the diaphragm are improved, thereby achieving the advantageous effect of increasing the sound pressure level (SPL) of the MEMS speaker.

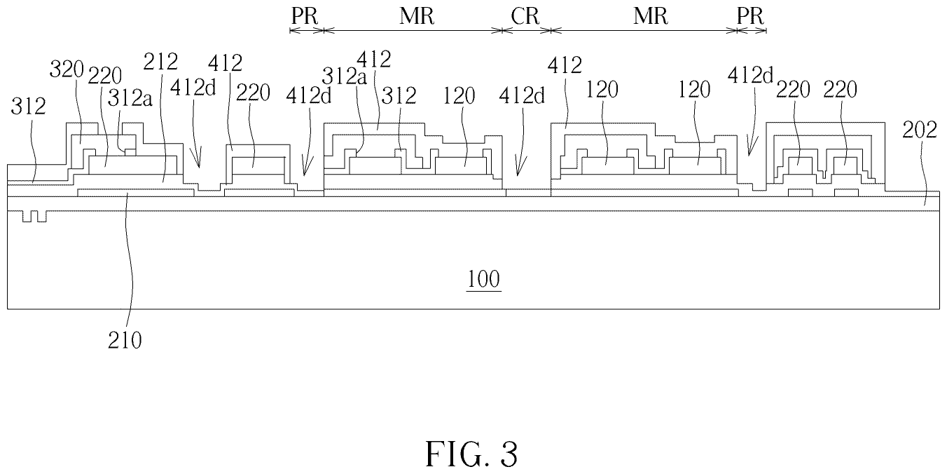

FIG. 3 to FIG. 5 are schematic diagrams illustrating a method for forming a semiconductor structure according to an embodiment of the present invention. In the figures, the same layers, regions, or elements are indicated by the same reference numerals or labels.

As shown in FIG. 3, a substrate 100 is provided. According to an embodiment of the present invention, for example, the substrate 100 may be a silicon substrate, but is not limited thereto. According to an embodiment of the present invention, a liner layer 202, such as a silicon oxide layer, may be formed on the substrate 100.

According to an embodiment of the present invention, a discontinuous metal pattern 210 may be formed on the liner layer 202, which at least defines a central region CR, a peripheral suspension region PR, and an annular coil region MR as shown in FIG. 1. The coil region MR is masked by the metal pattern 210. According to an embodiment of the present invention, a dielectric layer 212, such as a silicon oxide layer, is formed on the metal pattern 210. At the discontinuities of the metal pattern 210, the dielectric layer 212 is in direct contact with the liner layer 202.

According to an embodiment of the present invention, a metal pattern 220 and a coil pattern 120 may be formed on the dielectric layer 212, wherein the coil pattern 120 is formed within the annular coil region MR and overlaps with the underlying metal pattern 210.

According to an embodiment of the present invention, a dielectric layer 312 and an interconnection structure 320 may be further formed on the metal pattern 220 and the coil pattern 120, wherein the interconnection structure 320 is electrically connected to the metal pattern 220 and the coil pattern 120 via a conductive via 312a.

According to an embodiment of the present invention, a dielectric layer 412 may be further deposited on the dielectric layer 312 and the interconnection structure 320. According to an embodiment of the present invention, discontinuities 412d may be formed in the dielectric layer 412 by using a photolithography and etching process, at least exposing the dielectric layer 212 in the central region CR and the peripheral suspension region PR.

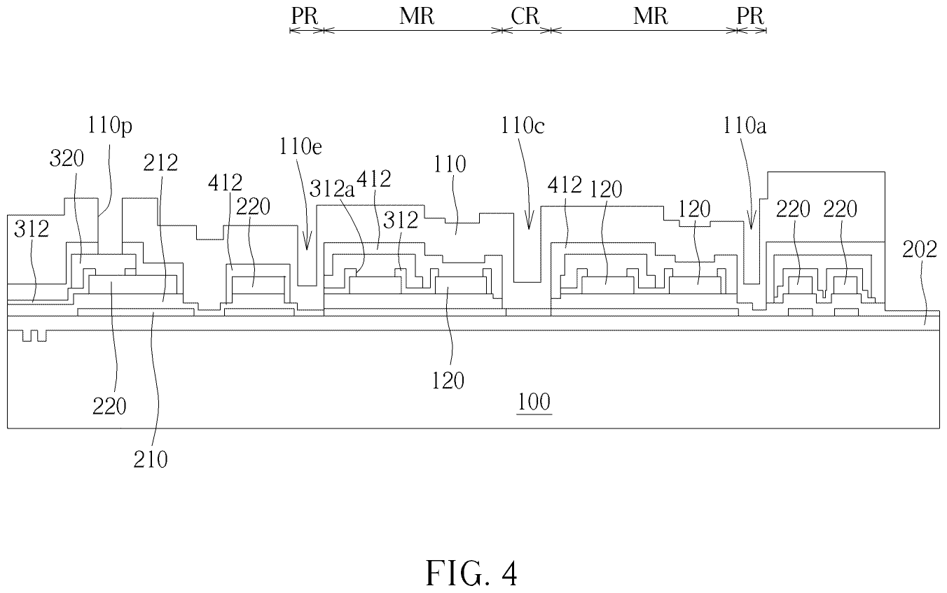

As illustrated in FIG. 4, a diaphragm 110 is formed on the dielectric layer 412 through a coating or deposition process. According to an embodiment of the present invention, the diaphragm 110 may comprise a polymer film. In accordance with an embodiment of the present invention, the polymer film may comprise a polyimide (PI) film or a polydimethylsiloxane (PDMS) film. According to another embodiment of the present invention, the diaphragm 110 may comprise a tensile dielectric film. According to an embodiment of the present invention, the tensile dielectric film may comprise a silicon nitride film.

According to an embodiment of the present invention, concave portions 110a, 110c, and 110e may be formed in the film 110 by a photolithography and etching process. The detailed features of the concave portions and convex portions of the diaphragm 110 (e.g., thickness ratio, bottom angle, top angle) have been described above and may be referred to FIG. 2 for more details. According to an embodiment of the present invention, an opening 110p may be further formed in the diaphragm 110 by a photolithography and etching process to expose a portion of the underlying interconnect structure 320.

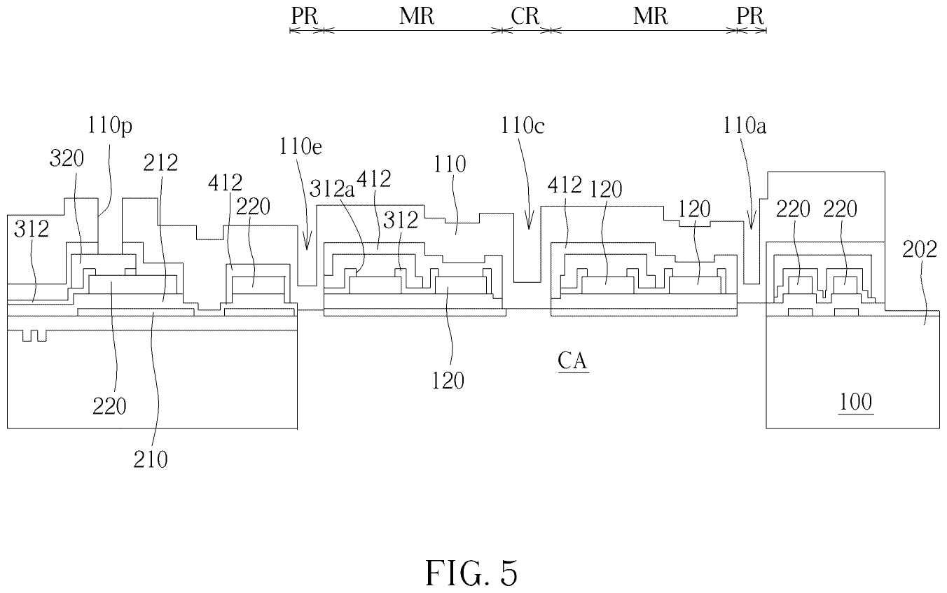

As shown in FIG. 5, a cavity CA is etched from the back side of the substrate 100 through a photolithography and etching process. The etching process is preferably a dry etching process. Since the etching is self-aligned to the metal pattern 210, after etching through the entire thickness of the substrate 100, the etching continues to etch the pad layer 202 and the dielectric layer 312 that are not covered by the metal pattern 210 until a portion of the diaphragm 110 is exposed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate having a cavity thereon;
a membrane suspended above the cavity and anchored to the substrate, wherein the membrane comprises a central region, a peripheral suspension region, and a coil region between the central region and the peripheral suspension region; and
a coil embedded in the coil region of the membrane, wherein the peripheral suspension region has a first concave portion and a first convex portion.

2. The semiconductor structure according to claim 1, wherein the membrane comprises a polymer film.

3. The semiconductor structure according to claim 2, wherein the polymer film comprises polyimide film or a polydimethylsiloxane film.

4. The semiconductor structure according to claim 1, wherein the membrane comprises a tensile dielectric film.

5. The semiconductor structure according to claim 4, wherein the tensile dielectric film comprises a silicon nitride film.

6. The semiconductor structure according to claim 1, wherein the first concave portion is contiguous with the first convex portion, and wherein an oblique sidewall is disposed between a bottom surface of the first concave portion and a top surface of the first convex portion.

7. The semiconductor structure according to claim 6, wherein a lower corner formed by an intersection of the oblique sidewall and the bottom surface of the first concave portion is an obtuse angle.

8. The semiconductor structure according to claim 6, wherein an upper corner formed by an intersection of the oblique sidewall and the top surface of the first convex portion is a rounded corner.

9. The semiconductor structure according to claim 1, wherein the first convex portion has a thickness X and the first concave portion has a thickness Y, wherein 0.2≤Y/X≤0.9.

10. The semiconductor structure according to claim 1, wherein the central region comprises a second concave portion.

11. A method for forming a semiconductor structure, comprising:
providing a substrate having a cavity thereon;
forming a membrane on the substrate, wherein the membrane is suspended above the cavity and anchored to the substrate, wherein the membrane comprises a central region, a peripheral suspension region, and a coil region between the central region and the peripheral suspension region; and
forming a coil in the coil region of the membrane, wherein the peripheral suspension region has a first concave portion and a first convex portion.

12. The method according to claim 11, wherein the membrane comprises a polymer film.

13. The method according to claim 12, wherein the polymer film comprises polyimide film or a polydimethylsiloxane film.

14. The method according to claim 11, wherein the membrane comprises a tensile dielectric film.

15. The method according to claim 14, wherein the tensile dielectric film comprises a silicon nitride film.

16. The method according to claim 11, wherein the first concave portion is contiguous with the first convex portion, and wherein an oblique sidewall is disposed between a bottom surface of the first concave portion and a top surface of the first convex portion.

17. The method according to claim 16, wherein a lower corner formed by an intersection of the oblique sidewall and the bottom surface of the first concave portion is an obtuse angle.

18. The method according to claim 16, wherein an upper corner formed by an intersection of the oblique sidewall and the top surface of the first convex portion is a rounded corner.

19. The method according to claim 11, wherein the first convex portion has a thickness X and the first concave portion has a thickness Y, wherein 0.2≤Y/X≤0.9.

20. The method according to claim 11, wherein the central region comprises a second concave portion.
